(19) United States
(12) Patent Application Publication
(10) Pub. No.: US 2025/0120274 A1
(43) Pub. Date: Apr. 10, 2025

(54) DISPLAY DEVICE

(71) Applicant: Samsung Display Co., LTD., Yongin-si (KR)

(72) Inventors: Hyeyoung KIM, Yongin-si (KR); Jinseuk KIM, Yongin-si (KR)

(21) Appl. No.: 18/906,020

(22) Filed: Oct. 3, 2024

(30) Foreign Application Priority Data
Oct. 4, 2023 (KR) 10-2023-0131935

(51) Int. Cl. H10K 59/131

(52) U.S. Cl. CPC H10K 59/131

(57) ABSTRACT

A display device includes a display panel including a plurality of pads, wherein the plurality of pads include a plurality of first pads, a plurality of second pads, and a plurality of third pads, wherein a first pad column, a second pad column, and a third pad column each include a first pad, a second pad, and a third pad, wherein only the first pad of the first pad column, the second pad of the second pad column, and the third pad of the third pad column are connected to a connection wire, wherein, in the first pad column, the second pad and the third pad that are not connected to the connection wire are in a floating state.

This application claims priority to Korean Patent Application No. 10-2023-0131935, filed on Oct. 4, 2023, and all the benefits accruing therefrom under 35 U.S.C. § 119, the content of which in its entirety is herein incorporated by reference.

### BACKGROUND

### 1. Field

One or more embodiments relate to a display device, and more particularly to a display device with improved reliability and quality.

### 2. Description of the Related Art

Display devices visually display data. Display devices may provide an image by using light-emitting diodes. The use of display devices has diversified, and various designs for improving the quality of display devices have been attempted.

### SUMMARY

One or more embodiments include a display device.

Additional embodiments will be set forth in part in the description which follows and, in part, will be apparent from the description, or may be learned by practice of the embodiments of the invention.

According to one or more embodiments, a display device includes a display panel including a plurality of pads, and a driving chip including a plurality of bumpers corresponding to the plurality of pads, wherein the plurality of pads include a plurality of first pads arranged in a first direction, a plurality of second pads arranged in the first direction and spaced apart from the first pads in a second direction crossing the first direction, and a plurality of third pads arranged in the first direction and spaced apart from the second pads in the second direction, wherein a first pad column, a second pad column, and a third pad column each include a first pad, a second pad, and a third pad arranged in the second direction, wherein the second pad column and the third pad column are spaced apart from the first pad column in the first direction, wherein only the first pad of the first pad column, the second pad of the second pad column, and the third pad of the third pad column are connected to a connection wire, wherein, in the first pad column, the second pad and the third pad that are not connected to the connection wire are in a floating state.

In an embodiment, a signal may not be applied to the second pad and the third pad of the first pad column that are not connected to the connection wire.

In an embodiment, when a signal is applied to the first pad connected to the connection wire, the signal may be applied to a sub-pixel circuit through the connection wire.

In an embodiment, in the second pad column, the first pad and the third pad that are not connected to the connection wire may be in a floating state.

In an embodiment, in the third pad column, the first pad and the second pad that are not connected to the connection wire may be in a floating state.

In an embodiment, a first pad group may include the first pad column, the second pad column, and the third pad column, wherein the first pad group may be arranged in the first direction.

In an embodiment, the first pads that are connected to the connection wire may be spaced apart from each other with two of the first pads disposed therebetween that are not connected to the connection wire.

In an embodiment, the second pads that are connected to the connection wire may be spaced apart from each other with two of the second pads disposed therebetween that are not connected to the connection wire.

In an embodiment, the third pads that are connected to the connection wire may be spaced apart from each other with two of the third pads disposed therebetween that are not connected to the connection wire.

According to one or more embodiments, a display device includes a display panel including a plurality of pads, and a driving chip including a plurality of bumpers corresponding to the plurality of pads, wherein the plurality of pads include a plurality of first pads arranged in a first direction, a plurality of second pads arranged in the first direction and spaced apart from the first pads in a second direction crossing the first direction, and a plurality of third pads arranged in the first direction and spaced apart from the second pads in the second direction, wherein a first pad column, a second pad column, a third pad column, and a fourth pad column each include a first pad, a second pad, and a third pad arranged in the second direction, wherein the first pad column, the second pad column, the third pad column, and the fourth pad column are spaced apart from one another in the first direction, wherein only the first pad of the first pad column, the second pad of the second pad column, the third pad of the third pad column, and the second pad of the fourth pad column are connected to a connection wire, wherein, in the first pad column, the second pad and the third pad that are not connected to the connection wire are in a floating state.

In an embodiment, in the second pad column, the first pad and the third pad that are not connected to the connection wire may be in a floating state.

In an embodiment, in the third pad column, the first pad and the second pad that are not connected to the connection wire may be in a floating state.

In an embodiment, In the fourth pad column, the first pad and the third pad that are not connected to the connection wire may be in a floating state.

In an embodiment, a second pad group may include the first pad column, the second pad column, the third pad column, and the fourth pad column, wherein the second pad group may be arranged in the first direction.

In an embodiment, the first pads that are connected to the connection wire may be spaced apart from each other with three of the first pads disposed therebetween that are not connected to the connection wire.

In an embodiment, the second pads that are connected to the connection wire may be spaced apart from each other with the second pad disposed therebetween that is not connected to the connection wire.

In an embodiment, the third pads that are connected to the connection wire may be spaced apart from each other with three of the third pads disposed therebetween that are not connected to the connection wire.

According to one or more embodiments, a display device includes a display panel including a plurality of pads, and a driving chip including a plurality of bumpers corresponding to the plurality of pads, wherein the plurality of pads include a plurality of first pads arranged in a first direction, and a plurality of second pads arranged in the first direction and spaced apart from the plurality of first pads in a second direction crossing the first direction, wherein a first pad column and a second pad column each include a first pad and a second pad arranged in the second direction, wherein the first pad column and the second pad column are spaced apart from each other in the first direction, wherein the first pad of the first pad column and the second pad of the second pad column are connected to a connection wire, wherein, in the first pad column, the second pad that is not connected to the connection wire is in a floating state.

In an embodiment, in the second pad column, the first pad that is not connected to the connection wire may be in a floating state.

In an embodiment, a third pad group may include the first pad column and the second pad column, wherein the third pad group may be arranged in the first direction.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1A is a perspective view of an electronic device, according to an embodiment;

FIG. 1B is an exploded perspective view of an electronic device, according to an embodiment;

FIG. 1C is a cross-sectional view of a circuit board connected to a display device, according to an embodiment;

FIG. 2 is a cross-sectional view of a display device, according to an embodiment;

FIG. 3 is a plan view of a display panel, according to an embodiment;

FIG. 4 is a schematic equivalent circuit diagram of a sub-pixel circuit included in a display device, according to an embodiment;

FIG. 5 is a schematic cross-sectional view of a display panel, according to an embodiment;

FIG. 6 is a schematic plan view of a plurality of pads arranged in a chip area of a display panel, according to an embodiment;

FIG. 7 is a schematic cross-sectional view of at least some of the plurality of pads of FIG. 6. according to an embodiment;

FIG. 8 is a schematic plan view of a plurality of pads arranged in a chip area of a display panel, according to an embodiment;

FIG. 9 is a schematic plan view of a plurality of pads arranged in a chip area of a display panel, according to an embodiment; and

FIG. 10 is a schematic plan view of a plurality of pads arranged in a chip area of a display panel, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the description allows for various changes and numerous embodiments, certain embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof are omitted.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, the expression “A and/or B” refers to A, B, or A and B. In addition, the expression “at least one of A and B” refers to A, B, or A and B.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

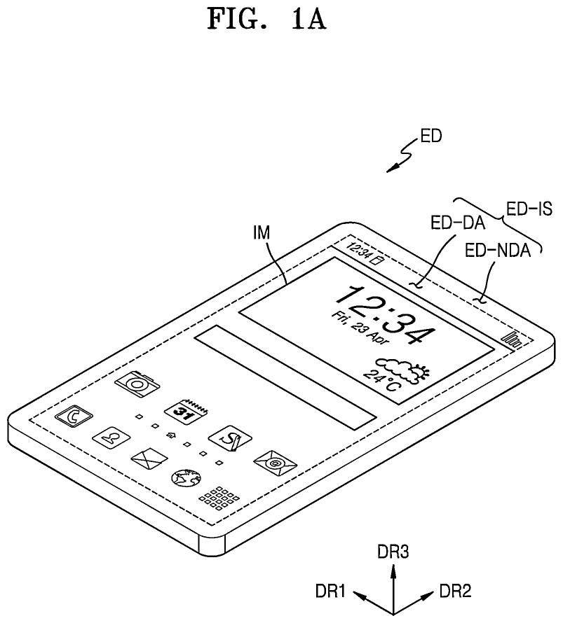

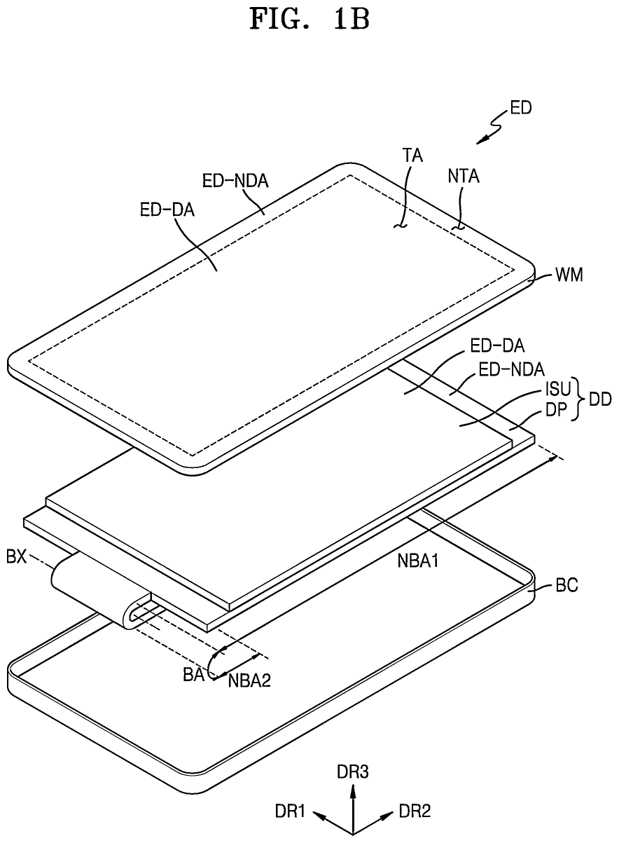

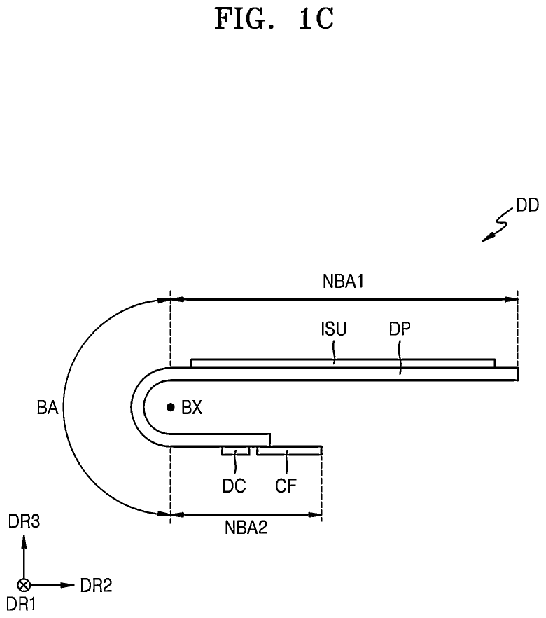

FIG. 1A is a perspective view of an electronic device ED, according to an embodiment. FIG. 1B is an exploded perspective view of the electronic device ED, according to an embodiment. FIG. 1C is a cross-sectional view of a circuit board CF connected to a display device DD, according to an embodiment.

In the present description, the electronic device ED of a mobile phone terminal is shown as an example. The electronic device ED described herein may be applied to large-sized electronic devices, such as a television and a monitor, and may also be applied to small and medium-sized electronic devices, such as a tablet personal computer, a vehicle navigation system, a game console, and a smartwatch.

In an embodiment and referring to FIG. 1A, the electronic device ED may display an image IM on a display surface ED-IS. Icon images are shown as an example of the image IM. The display surface ED-IS is directed parallel to a plane defined by a first direction DR1 and a second direction DR2. A third direction DR3 indicates a normal direction of the display surface ED-IS, that is, a thickness direction of the electronic device ED.

As used herein, the phrase “when viewed in plan or in a plan view” may refer to when viewed in the third direction DR3. The third direction DR3 differentiates a front (or top) surface and a rear (or bottom) surface of each layer or unit described below. However, a combination of the first to third directions DR1 to DR3 may be changed to another combination.

In an embodiment and referring to FIGS. 1B and 1C, the electronic device ED may include a window WM, the display device DD, and an accommodation member BC. Although not shown, the electronic device ED may further include an optical member arranged between the window WM and the display device DD. The optical member may include a polarizer.

In an embodiment, the window WM may be disposed on the display device DD and may externally transmit an image provided from the display device DD. The window WM includes a transmission area TA and a non-transmission area NTA. The transmission area TA may overlap a display area ED-DA and may have a shape corresponding to the display area ED-DA. The window WM may include a base layer and functional layers disposed on the base layer. The functional layers may include a protective layer and an anti-fingerprint layer. The base layer of the window WM may be formed of glass, sapphire, or plastic.

In an embodiment, the non-transmission area NTA may overlap a non-display area ED-NDA and may have a shape corresponding to the non-display area ED-NDA. The non-transmission area NTA may be an area having a relatively low light transmittance compared to that of the transmission area TA. The non-transmission area NTA may be defined by a bezel pattern arranged in a partial region of the base layer of the window WM, and an area in which the bezel pattern is not arranged may be defined as the transmission area TA. However, one or more embodiments are not limited thereto, and the non-transmission area NTA may be omitted.

According to an embodiment, a display panel DP may be one of a liquid crystal display panel, an electrophoretic display panel, a microelectromechanical system (MEMS) display panel, an electrowetting display panel, an organic light-emitting display panel, an inorganic light-emitting display panel, and a quantum dot light-emitting display panel, and is not particularly limited. Hereinafter, it is assumed that the display panel DP is an organic light-emitting display panel.

In an embodiment, an input sensor ISU may include one of a capacitive sensor, an optical sensor, an ultrasonic sensor, and an inductive sensor. The input sensor ISU may be formed on the display panel DP through a continuous process, or may be manufactured separately and then attached to an upper side of the display panel DP through an adhesive layer, and is not limited to any one embodiment.

In an embodiment, the display device DD may further include a driving chip DC and the circuit board CF. Although an embodiment in which the driving chip DC is mounted on the display panel DP is shown, the invention is not limited thereto. The driving chip DC may generate a driving signal required for an operation of the display panel DP based on a control signal transferred from the circuit board CF.

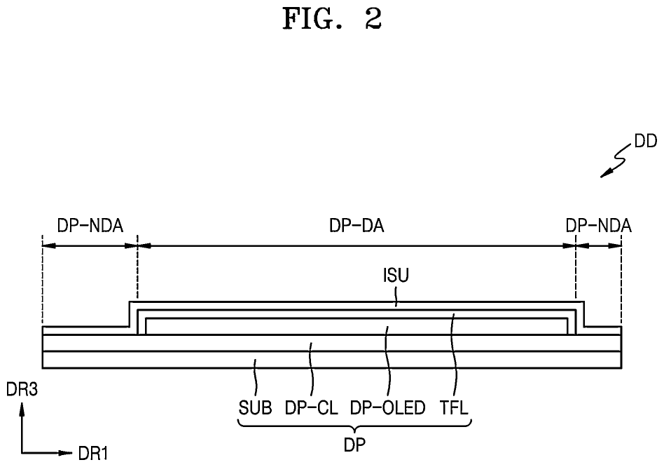

In an embodiment, the circuit board CF electrically bonded to the display panel DP may be bent and disposed on a rear surface of the display panel DP. The accommodation member BC may receive the display device DD and may be coupled to the window WM. The circuit board CF may be disposed at an end of a base substrate SUB (refer to FIG. 2) and may be electrically connected to a circuit element layer DP-CL (refer to FIG. 2). Although not shown, the electronic device ED may further include a mainboard, and electronic modules, a camera module, and a power module mounted on the mainboard.

In an embodiment, the display panel DP may include a bending area BA, and a first non-bending area NBA1 and a second non-bending area NBA2 spaced apart from each other in the third direction DR3 with the bending area BA disposed therebetween.

In an embodiment, the bending area BA may be defined as an area where the display panel DP is bent along a virtual bending axis BX extending in the first direction DR1. The first non-bending area NBA1 may be defined as an area overlapping the transmission area TA, and the second non-bending area NBA2 may be defined as an area to which the circuit board CF is connected.

In an embodiment, when the bending area BA is bent with respect to the bending axis BX, the circuit board CF and the driving chip DC may be bent in a direction of the rear surface of the display panel DP and disposed on the rear surface of the display panel DP.

Although not shown, in an embodiment, additional configurations may be arranged to compensate for a step between the circuit board CF and the rear surface of the display panel DP caused by the bending area BA.

According to an embodiment, in the second direction DR2, a width of the first non-bending area NBA1 may be greater than widths of the bending area BA and the second non-bending area NBA2. However, the invention is not limited thereto, and a width of the bending area BA in the second direction DR2 may decrease in a direction from the first non-bending area NBA1 to the second non-bending area NBA2 and is not limited to any one embodiment.

In an embodiment, a mobile phone terminal has been described above as an example of the electronic device ED. However, in an embodiment, it is sufficient for the electronic device ED to include two or more electrically bonded electronic components. The display panel DP and the driving chip DC mounted on the display panel DP may correspond to different electronic components, respectively, and these alone may constitute the electronic device ED, and the invention is not limited thereto.

In an embodiment, for example, the display panel DP and the circuit board CF connected to the display panel DP may be sufficient to constitute the electronic device ED, and a mainboard and an electronic module mounted on the mainboard may be sufficient to constitute the electronic device ED. Hereinafter, the electronic device ED according to one or more embodiments will be described focusing on a bonding structure between the display panel DP and the driving chip DC mounted on the display panel DP.

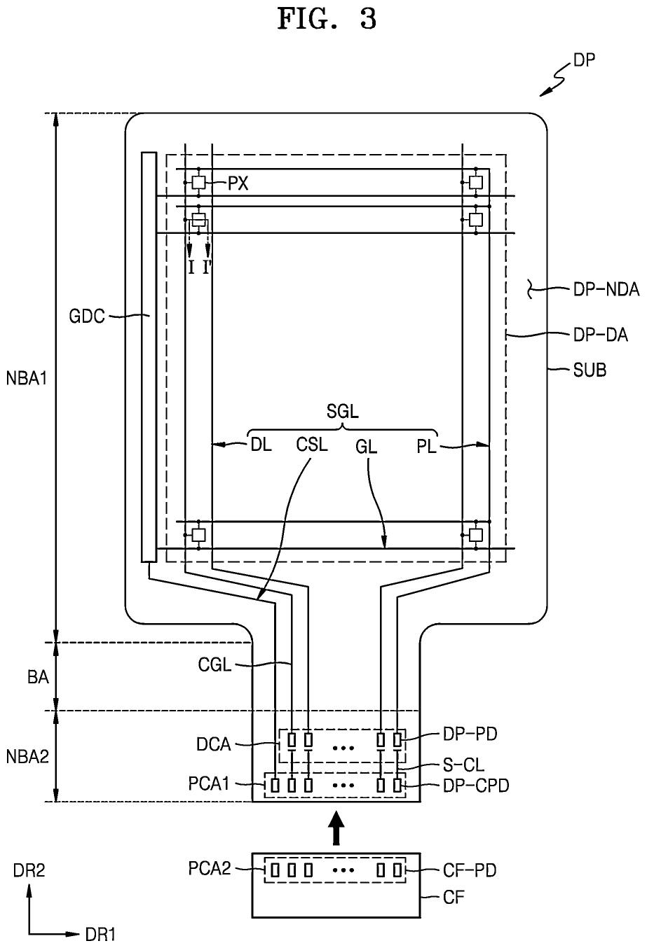

FIG. 2 is a cross-sectional view of the display device DD, according to an embodiment. In FIG. 2, areas corresponding to the bending area BA and the second non-bending area NBA2 of the display panel DP described with reference to FIG. 1C are omitted. FIG. 3 is a plan view of the display panel DP, according to an embodiment.

In an embodiment and referring to FIG. 2, the display panel DP includes the base substrate SUB, and the circuit element layer DP-CL, a display element layer DP-OLED, and an encapsulation layer TFL disposed on the base substrate SUB. The input sensor ISU may be disposed on the encapsulation layer TFL.

In an embodiment, the display panel DP includes a display area DP-DA and a non-display area DP-NDA. The display area DP-DA of the display panel DP corresponds to the display area ED-DA shown in FIG. 1A or the transmission area TA shown in FIG. 1B, and the non-display area DP-NDA of the display panel DP corresponds to the non-display area ED-NDA shown in FIG. 1A or the non-transmission area NTA shown in FIG. 1B.

In an embodiment, the base substrate SUB may include at least one plastic film. The base substrate SUB is a flexible substrate and may include a plastic substrate, a glass substrate, a metal substrate, or an organic/inorganic composite substrate.

In an embodiment, the circuit element layer DP-CL includes at least one intermediate insulating layer and a circuit element. The intermediate insulating layer includes at least one intermediate inorganic layer and at least one intermediate organic layer. The circuit element includes signal lines and a pixel driving circuit.

In an embodiment, the display element layer DP-OLED includes a plurality of organic light-emitting diodes. The display element layer DP-OLED may further include an organic layer such as a pixel-defining layer. The encapsulation layer TFL encapsulates the display element layer DP-OLED. As an example, the encapsulation layer TFL may include a stack structure of an inorganic layer/an organic layer/an inorganic layer. The encapsulation layer TFL protects the display element layer DP-OLED from moisture, oxygen, and a foreign substance such as dust particles. However, the invention is not limited thereto, and the encapsulation layer TFL may further include an additional insulating layer. For example, an optical insulating layer for controlling the refractive index may be further included.

In an embodiment, an encapsulation substrate may be provided instead of the encapsulation layer TFL. In this case, the encapsulation substrate may face the base substrate SUB and may be coupled to the base substrate SUB via a separate adhesive member. The circuit element layer DP-CL and the display element layer DP-OLED may be disposed between the encapsulation substrate and the base substrate SUB.

In an embodiment, the input sensor ISU may be directly disposed on the display panel DP. As used herein, the phrase “an element A is directly disposed on an element B” means that no adhesive layer is disposed between the element A and the element B. In an embodiment, the input sensor ISU may be manufactured through a continuous process with the display panel DP. However, the invention is not limited thereto, and the input sensor ISU may be provided as an individual panel and be coupled to the display panel DP through and adhesive layer. As another example, the input sensor ISU may be omitted.

In an embodiment and referring to FIG. 3, the display panel DP may include a plurality of pixels PX, a gate driving circuit GDC, a plurality of signal lines SGL, and a plurality of pads DP-PD and a plurality of pads DP-CPD.

In an embodiment, the pixels PX are arranged in the display area DP-DA. Each of the pixels PX includes an organic light-emitting diode and a pixel driving circuit connected thereto. The gate driving circuit GDC and the signal lines SGL may be included in the circuit element layer DP-CL shown in FIG. 2.

In an embodiment, the gate driving circuit GDC is configured to sequentially output gate signals to a plurality of gate lines GL. The gate driving circuit GDC may include a plurality of thin-film transistors formed through the same process as that of a driving circuit of the pixels PX, for example, a low temperature polycrystalline silicon (LTPS) process or a low temperature polycrystalline oxide (LTPO) process. The display panel DP may further include another driving circuit configured to provide a light emission control signal to the pixels PX.

In an embodiment, the signal lines SGL include the gate lines GL, data lines DL, a power line PL, and a control signal line CSL. Each of the gate lines GL is connected to a corresponding pixel PX among the pixels PX, and each of the data lines DL is connected to a corresponding pixel PX among the pixels PX. The power line PL is connected to the pixels PX. The control signal line CSL may be configured to provide control signals to a scan driving circuit.

In an embodiment, the signal lines SGL overlap the display area DP-DA and the non-display area DP-NDA. Each of the signal lines SGL may include a pad portion and a line portion. The line portion overlaps the display area DP-DA and the non-display area DP-NDA. The pad portion is connected to an end of the line portion. The pad portion may overlap a pad area described below.

In an embodiment, the display panel DP may include display pads. The display pads may include the pads DP-PD arranged in a chip area DCA and the pads DP-CPD arranged in a first pad area PCA1. The pads DP-PD arranged in the chip area DCA and the pads DP-CPD arranged in the first pad area PCA1 may be arranged in the second non-bending area NBA2.

In an embodiment, the plurality of pads DP-PD may be arranged in the chip area DCA. The driving chip DC (refer to FIG. 1B) may be mounted on the chip area DCA. The plurality of pads DP-PD are electrically connected to the driving chip DC to transfer an electrical signal received from the driving chip DC to the signal lines SGL. Hereinafter, an arrangement of the plurality of pads DP-PD and a connection wire CGL connected to the plurality of pads DP-PD in the following drawings will be described in more detail.

In an embodiment, the pads DP-CPD may also be arranged in the first pad area PCA1. The pads DP-CPD may be arranged in the first direction DR1. The pads DP-PD in the chip area DCA and the pads DP-CPD in the first pad area PCA1 may be connected to each other through a bridge signal line S-CL.

In an embodiment, the circuit board CF may include substrate pads CF-PD electrically connected to the display panel DP. The substrate pads CF-PD may be arranged in a second pad area PCA2 defined on the circuit board CF. The substrate pads CF-PD may be arranged in the first direction DR1.

In addition, in an embodiment, the pads DP-CPD in the first pad area PCA1 and the pads CF-PD in the second pad area PCA2 may be arranged in 1:1 correspondence and are not limited to any one embodiment.

In an embodiment, the second pad area PCA2 of the circuit board CF may be disposed on the first pad area PCA1. The pads DP-CPD in the first pad area PCA1 are electrically connected to the pads CF-PD included in the circuit board CF to transfer electrical signals received from the circuit board CF to the pads DP-CPD in the first pad area PCA1 or the pads DP-PD in the chip area DCA. The circuit board CF may be rigid or flexible. For example, when the circuit board CF is flexible, a flexible printed circuit board may be provided as the circuit board CF.

In an embodiment, the circuit board CF may include a timing control circuit configured to control an operation of the display panel DP. The timing control circuit may be mounted on the circuit board CF in the form of an integrated chip. In addition, although not shown, the circuit board CF may include an input sensing circuit configured to control the input sensor ISU (see FIG. 2).

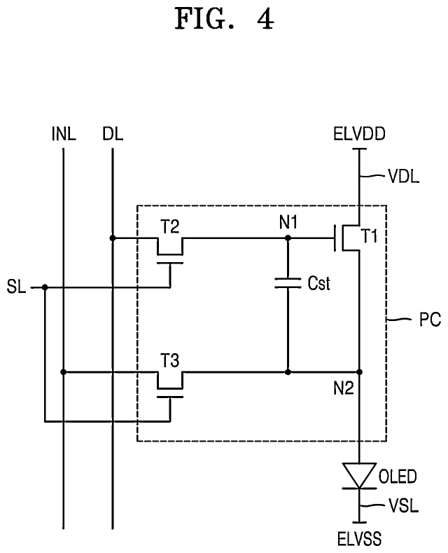

FIG. 4 is a schematic equivalent circuit diagram of any one sub-pixel circuit PC included in a display device, according to an embodiment.

In an embodiment and referring to FIG. 4, the sub-pixel circuit PC may include a plurality of thin-film transistors and at least one capacitor. In an embodiment, the sub-pixel circuit PC may include a first thin-film transistor T1, a second thin-film transistor T2, a third thin-film transistor T3, and a storage capacitor Cst.

In an embodiment, each of the first thin-film transistor T1, the second thin-film transistor T2, and the third thin-film transistor T3 may be an oxide semiconductor thin-film transistor including a semiconductor layer composed of an oxide semiconductor, or a silicon semiconductor thin-film transistor including a semiconductor layer composed of polysilicon. Each thin-film transistor may include a first electrode and a second electrode, and depending on the type of a thin-film transistor, the first electrode may be one of a source electrode and a drain electrode and the second electrode may be the other of the source electrode and the drain electrode. In addition, each thin-film transistor may include a gate electrode.

In an embodiment, the first thin-film transistor T1 may be a driving thin-film transistor. A first electrode of the first thin-film transistor T1 may be connected to a driving voltage line VDL configured to supply a driving power voltage ELVDD, and a second electrode of the first thin-film transistor T1 may be connected to a pixel electrode of an organic light-emitting diode OLED. A gate electrode of the first thin-film transistor T1 may be connected to a first node N1. The first thin-film transistor T1 may be configured to control an amount of current flowing through the organic light-emitting diode OLED from the driving power voltage ELVDD in response to a voltage of the first node N1.

In an embodiment, the second thin-film transistor T2 may be a switching thin-film transistor. A first electrode of the second thin-film transistor T2 may be connected to a data line DL, and a second electrode of the second thin-film transistor T2 may be connected to the first node N1. A gate electrode of the second thin-film transistor T2 may be connected to a scan line SL. When a scan signal is supplied to the scan line SL, the second thin-film transistor T2 may be turned on to electrically connect the data line DL and the first node N1 to each other.

In an embodiment, the third thin-film transistor T3 may be an initialization thin-film transistor and/or a sensing thin-film transistor. A first electrode of the third thin-film transistor T3 may be connected to a second node N2, and a second electrode of the third thin-film transistor T3 may be connected to an initialization voltage line INL. A gate electrode of the third thin-film transistor T3 may be connected to the scan line SL.

In an embodiment, when a scan signal is supplied to the scan line SL, the third thin-film transistor T3 may be turned on to electrically connect the initialization voltage line INL and the second node N2 to each other. In some embodiments, the third thin-film transistor T3 may be turned on according to a signal received through the scan line SL to transfer an initialization voltage from the initialization voltage line INL to the pixel electrode of the organic light-emitting diode OLED and initialize the pixel electrode of the organic light-emitting diode OLED.

In an embodiment, when a scan signal is supplied to the scan line SL, the third thin-film transistor T3 may be turned on to sense characteristic information regarding the organic light-emitting diode OLED. The third thin-film transistor T3 may have both of the above-described functions as an initialization thin-film transistor and a sensing thin-film transistor or may have either function. An initialization operation and a sensing operation of the third thin-film transistor T3 may each be performed individually or may be performed simultaneously. When the third thin-film transistor T3 has the function as a sensing thin-film transistor, the initialization voltage line INL may be referred to as a sensing line.

In an embodiment, the storage capacitor Cst may be connected between the first node N1 and the second node N2. For example, a first capacitor plate of the storage capacitor Cst may be connected to the gate electrode of the first thin-film transistor T1, and a second storage plate of the storage capacitor Cst may be connected to the pixel electrode of the organic light-emitting diode OLED.

In an embodiment, an opposite electrode of the organic light-emitting diode OLED may be connected to a common voltage line VSL configured to provide a common power voltage ELVSS.

In an embodiment, although FIG. 4 shows the sub-pixel circuit PC including three thin-film transistors and one storage capacitor, one or more embodiments are not limited thereto. In another embodiment, the number of thin-film transistors or the number of storage capacitors may be variously modified according to the design of the sub-pixel circuit PC.

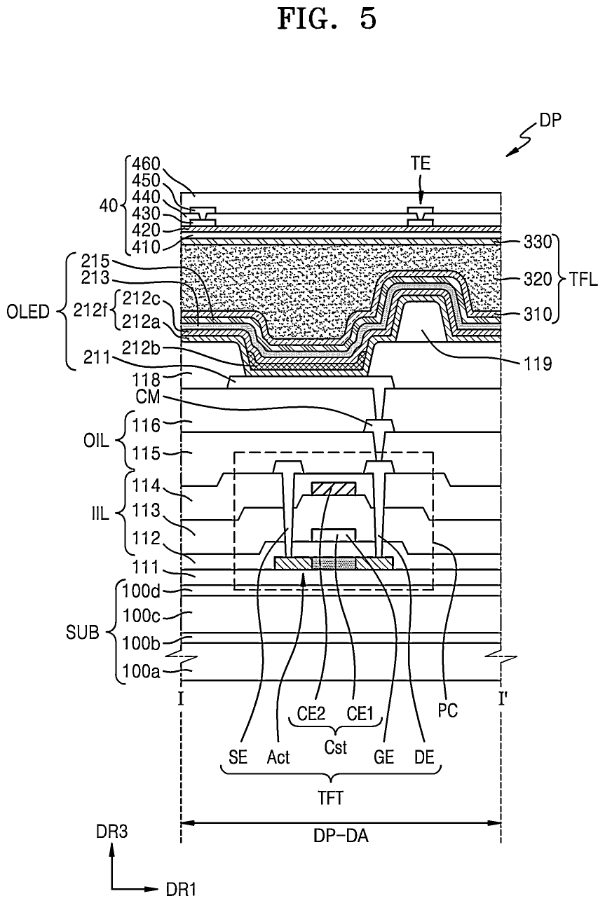

FIG. 5 is a schematic cross-sectional view of the display panel DP, according to an embodiment. More specifically, FIG. 5 is a schematic cross-sectional view of the display panel DP of FIG. 3, taken along a line I-I′ of FIG. 3.

In an embodiment and referring to FIG. 5, the base substrate SUB may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the base substrate SUB.

In an embodiment, at least one of the first base layer 100a and the second base layer 100c may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

In an embodiment, the first barrier layer 100b and the second barrier layer 100d are barrier layers that prevent intrusion of external foreign substances and may each have a single-layer or multi-layer structure including an inorganic material such as silicon nitride (SiNₓ), silicon oxide (SiO₂) and/or silicon oxynitride (SiON).

In an embodiment, a buffer layer 111 may be disposed on the base substrate SUB. The buffer layer 111 may include an inorganic insulating material such as silicon nitride (SiNₓ), silicon oxynitride (SiON) or silicon oxide (SiO₂), and may have a single-layer or multi-layer structure including the above-described inorganic insulating material.

In an embodiment, an inorganic insulating layer IIL may be disposed on the buffer layer 111. The inorganic insulating layer IIL may include a first gate insulating layer 112, a second gate insulating layer 113, and an interlayer insulating layer 114.

In an embodiment, the sub-pixel circuit PC may be arranged in the display area DA. The sub-pixel circuit PC may include a thin-film transistor TFT and the storage capacitor Cst. The thin-film transistor TFT may include a semiconductor layer Act, a gate electrode GE, a source electrode SE, and a drain electrode DE.

In an embodiment, the semiconductor layer Act may be disposed on the buffer layer 111. The semiconductor layer Act may include polysilicon. In another embodiment, the semiconductor layer Act may include amorphous silicon, an oxide semiconductor, or an organic semiconductor. The semiconductor layer Act may include a channel region, and a drain region and a source region respectively arranged on both sides of the channel region.

In an embodiment, the gate electrode GE may be disposed over the semiconductor layer Act. The gate electrode GE may overlap the channel region. The gate electrode GE may include a low-resistance metal material. The gate electrode GE may include a conductive material including molybdenum (Mo), aluminum (Al), copper (Cu), titanium (Ti), etc., and may have a multi-layer or single-layer structure including the above-described material.

In an embodiment, the first gate insulating layer 112 may be disposed between the semiconductor layer Act and the gate electrode GE. The first gate insulating layer 112 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, the second gate insulating layer 113 may be disposed on the gate electrode GE. The second gate insulating layer 113 may cover the gate electrode GE. The second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

In an embodiment, a second capacitor plate CE2 of the storage capacitor Cst may be disposed on the second gate insulating layer 113. The second capacitor plate CE2 may overlap the gate electrode GE disposed below. In this regard, the gate electrode GE and the second capacitor plate CE2 overlapping each other with the second gate insulating layer 113 therebetween may constitute the storage capacitor Cst. That is, the gate electrode GE may serve as a first capacitor plate CE1 of the storage capacitor Cst.

In an embodiment and as described above, the storage capacitor Cst and the thin-film transistor TFT may overlap each other. However, the invention is not limited thereto. For example, the storage capacitor Cst may not overlap the thin-film transistor TFT. That is, the first capacitor plate CE1 of the storage capacitor Cst may be spaced apart from the gate electrode GE of the thin-film transistor TFT as a separate element from the gate electrode GE of the thin-film transistor TFT.

In an embodiment, the second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

In an embodiment, the interlayer insulating layer 114 may be disposed on the second capacitor plate CE2. The interlayer insulating layer 114 may cover the second capacitor plate CE2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The interlayer insulating layer 114 may have a single-layer or multi-layer structure including the above-described inorganic insulating material.

In an embodiment, each of the drain electrode DE and the source electrode SE may be on the interlayer insulating layer 114. Each of the drain electrode DE and the source electrode SE may be connected to the semiconductor layer Act through a contact hole defined in the first gate insulating layer 112, the second gate insulating layer 113, and the interlayer insulating layer 114. The drain electrode DE and the source electrode SE may include a highly conductive material. The drain electrode DE and the source electrode SE may include a conductive material including molybdenum (Mo), aluminum (Al), copper (Cu), titanium (Ti), etc., and may have a multi-layer or single-layer structure including the above-described material. For example, the drain electrode DE and the source electrode SE may have a multi-layer structure of titanium (Ti)/aluminum (Al)/titanium (Ti).

In an embodiment, an organic insulating layer OIL may be disposed on the inorganic insulating layer IIL. The organic insulating layer OIL may include a first organic insulating layer 115 and a second organic insulating layer 116. Although FIG. 5 shows the organic insulating layer OIL including two layers, the invention is not limited thereto. The organic insulating layer OIL may include three or four layers.

In an embodiment, the first organic insulating layer 115 may cover the drain electrode DE and the source electrode SE. The first organic insulating layer 115 may include an organic insulating material such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

In an embodiment, a connection electrode CM may be disposed on the first organic insulating layer 115. In this regard, the connection electrode CM may be connected to the drain electrode DE or the source electrode SE through a contact hole in the first organic insulating layer 115. The connection electrode CM may include a highly conductive material. The connection electrode CM may include a conductive material including molybdenum (Mo), aluminum (Al), copper (Cu), titanium (Ti), etc., and may have a multi-layer or single-layer structure including the above-described material. For example, the connection electrode CM may have a multi-layer structure of titanium (Ti)/aluminum (Al)/titanium (Ti).

In an embodiment, the second organic insulating layer 116 may be disposed on the connection electrode CM. The second organic insulating layer 116 may cover the connection electrode CM. The second organic insulating layer 116 may include the same material as or a different material than that of the first organic insulating layer 115.

In an embodiment, a light-emitting diode may be disposed on the second organic insulating layer 116. For example, the organic light-emitting diode OLED may be disposed on the second organic insulating layer 116. In another embodiment, although not shown, an inorganic light-emitting diode may be disposed on the second organic insulating layer 116.

In an embodiment, the organic light-emitting diode OLED may emit red, green, or blue light, or may emit red, green, blue, or white light. The organic light-emitting diode OLED may include a first electrode 211, an emission layer 212b, a functional layer 212f, a second electrode 213, and a capping layer 215. The first electrode 211 may be a pixel electrode (e.g., an anode) of the organic light-emitting diode OLED, and the second electrode 213 may be an opposite electrode (e.g., a cathode) of the organic light-emitting diode OLED.

In an embodiment, the first electrode 211 may be disposed on the second organic insulating layer 116. The first electrode 211 may be electrically connected to the connection electrode CM through a contact hole defined in the second organic insulating layer 116. The first electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 211 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the first electrode 211 may further include a layer on/under the above-described reflective layer and formed of ITO, IZO, ZnO, or In₂O₃. For example, the first electrode 211 may have a multi-layer structure of ITO/Ag/ITO.

In an embodiment, a pixel-defining layer 118 having defined therein an opening exposing at least a portion of the first electrode 211 may be disposed on the first electrode 211. An emission area of light emitted from the organic light-emitting diode OLED may be defined by the opening defined in the pixel-defining layer 118. For example, a width of the opening may correspond to a width of the emission area.

In an embodiment, the pixel-defining layer 118 may include an organic insulating material. In another embodiment, the pixel-defining layer 118 may include an inorganic insulating material, such as silicon nitride, silicon oxynitride, or silicon oxide. In still another embodiment, the pixel-defining layer 118 may include an organic insulating material and an inorganic insulating material. In an embodiment, the pixel-defining layer 118 may include a light-blocking material. The light-blocking material may include carbon black, carbon nanotubes, resin or paste including black dye, metal particles, for example, nickel, aluminum, molybdenum, and alloys thereof, metal oxide particles (e.g., chromium oxide), or metal nitride particles (e.g., chromium nitride). When the pixel-defining layer 118 includes a light-blocking material, the reflection of external light caused by metal structures disposed below the pixel-defining layer 118 may be reduced.

In an embodiment, a spacer 119 may be disposed on the pixel-defining layer 118. The spacer 119 may include an organic insulating material, such as polyimide. In another embodiment, the spacer 119 may include an inorganic insulating material such as silicon nitride (SiNₓ) or silicon oxide (SiO₂), or may include an organic insulating material and an inorganic insulating material.

In an embodiment, the spacer 119 may include the same material as that of the pixel-defining layer 118. In this case, the pixel-defining layer 118 and the spacer 119 may be formed together during a mask process using a halftone mask or the like. In another embodiment, the spacer 119 and the pixel-defining layer 118 may include different materials, respectively.

In an embodiment, the emission layer 212b may be arranged in the opening of the pixel-defining layer 118. The emission layer 212b may include a high-molecular weight or low-molecular weight organic material emitting light of a certain color.

In an embodiment, the functional layer 212f may include a first functional layer 212a and a second functional layer 212c. The first functional layer 212a may be disposed between the first electrode 211 and the emission layer 212b, and the second functional layer 212c may be disposed between the emission layer 212b and the second electrode 213. However, at least one of the first functional layer 212a or the second functional layer 212c may be omitted. Hereinafter, an embodiment where each of the first functional layer 212a and the second functional layer 212c is arranged will be mainly described.

In an embodiment, the first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be common layers that entirely cover the base substrate SUB as the second electrode 213 described below does.

In an embodiment, the second electrode 213 may be disposed on the functional layer 212f. The second electrode 213 may include a conductive material having a low work function. For example, the second electrode 213 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another embodiment, the second electrode 213 may further include a layer, such as ITO, IZO, ZnO, or In2O3, on a (semi) transparent layer including the above-described material.

In an embodiment, the capping layer 215 may be disposed on the second electrode 213. The capping layer 215 may include lithium fluoride (LiF), an inorganic material and/or an organic material.

In an embodiment, the encapsulation layer TFL may be disposed on the organic light-emitting diode OLED. The encapsulation layer TFL may cover the organic light-emitting diode OLED. The encapsulation layer TFL may be disposed on the second electrode 213 and/or the capping layer 215. In an embodiment, the encapsulation layer TFL may include at least one inorganic encapsulation layer and at least one organic encapsulation layer. FIG. 5 shows the encapsulation layer TFL including a first inorganic encapsulation layer 310, an organic encapsulation layer 320, and a second inorganic encapsulation layer 330 sequentially stacked on one another.

In an embodiment, the first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may have a single-layer or multi-layer structure including the above-described material. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate.

In an embodiment, an input sensing layer 40 may be disposed on the encapsulation layer TFL. The input sensing layer 40 may include a first touch insulating layer 410, a second touch insulating layer 420, a first conductive layer 430, a third touch insulating layer 440, a second conductive layer 450, and a planarization layer 460.

In an embodiment, the first touch insulating layer 410 may be disposed on the second inorganic encapsulation layer 330, and the second touch insulating layer 420 may be disposed on the first touch insulating layer 410. In an embodiment, the first touch insulating layer 410 and the second touch insulating layer 420 may include an inorganic insulating material and/or an organic insulating material. For example, the first touch insulating layer 410 and the second touch insulating layer 420 may include an inorganic insulating material such as silicon oxide, silicon nitride and/or silicon oxynitride.

In an embodiment, at least one of the first touch insulating layer 410 and the second touch insulating layer 420 may be omitted. For example, the first touch insulating layer 410 may be omitted. In this case, the second touch insulating layer 420 may be disposed on the second inorganic encapsulation layer 330, and the first conductive layer 430 may be disposed on the second touch insulating layer 420.

In an embodiment, the first conductive layer 430 may be disposed on the second touch insulating layer 420, and the third touch insulating layer 440 may be disposed on the first conductive layer 430. In an embodiment, the third touch insulating layer 440 may include an inorganic insulating material and/or an organic insulating material. For example, the third touch insulating layer 440 may include an inorganic insulating material such as silicon oxide, silicon nitride and/or silicon oxynitride.

In an embodiment, the second conductive layer 450 may be disposed on the third touch insulating layer 440. A touch electrode TE of the input sensing layer 40 may have a structure in which the first conductive layer 430 and the second conductive layer 450 are connected to each other. In another embodiment, the touch electrode TE may be formed in one of the first conductive layer 430 and the second conductive layer 450 and may include a metal line provided in the corresponding conductive layer. Each of the first conductive layer 430 and the second conductive layer 450 may include at least one of aluminum (Al), copper (Cu), titanium (Ti), molybdenum (Mo), and indium tin oxide (ITO), and may have a single-layer or multi-layer structure including the above-described material. For example, each of the first conductive layer 430 and the second conductive layer 450 may have a three-layer structure of a titanium layer/an aluminum layer/a titanium layer.

In an embodiment, the planarization layer 460 may cover the second conductive layer 450. The planarization layer 460 may include an organic insulating material.

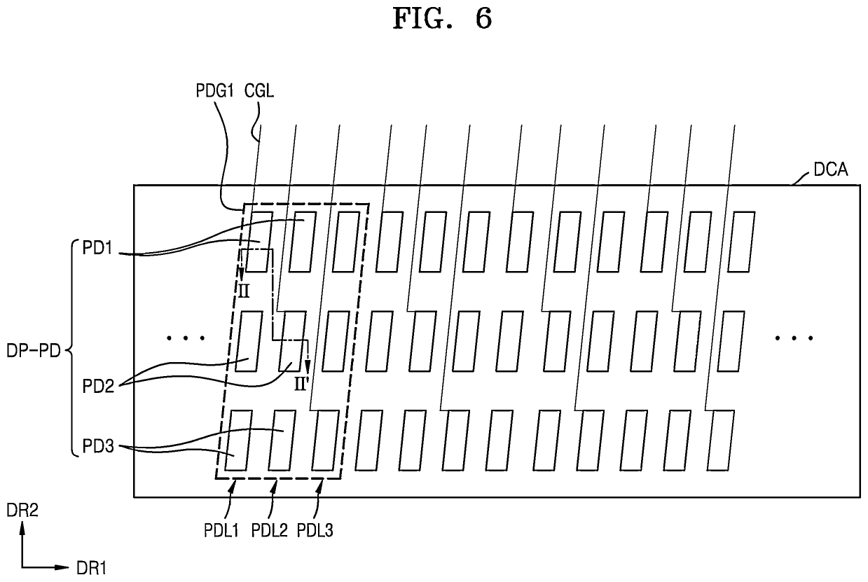

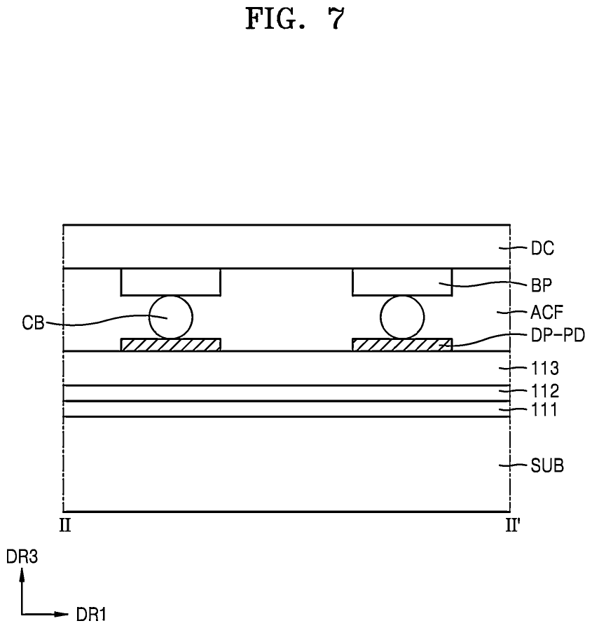

FIG. 6 and FIGS. 8 to 10 are schematic plan views of the plurality of pads DP-PD arranged in the chip area DCA of a display panel, according to embodiments. FIG. 7 is a schematic cross-sectional view of at least some of the plurality of pads DP-PD of FIG. 6, according to an embodiment. FIG. 7 is a schematic cross-sectional view of the display panel of FIG. 6, taken along a line II-II′ of FIG. 6.

In an embodiment and referring to FIG. 6, the plurality of pads DP-PD may be arranged in the chip area DCA of the display panel DP (refer to FIG. 3). The plurality of pads DP-PD in the chip area DCA may include first pads PD1, second pads PD2, and third pads PD3. The first pads PD1 may be arranged in the first direction DR1. The second pads PD2 may be arranged in the first direction DR1 and may be spaced apart from the first pads PD1 in the second direction DR2. The third pads PD3 may be arranged in the first direction DR1 and may be spaced apart from the second pads PD2 in the second direction DR2.

In an embodiment, a shortest distance between the first pads PD1 and the display area DP-DA (refer to FIG. 3) of the display panel DP may be the smallest, and a shortest distance between the third pads PD3 and the display area DP-DA of the display panel DP may be the largest. A shortest distance between the second pads PD2 and the display area DP-DA of the display panel DP may be halfway between the shortest distance between the first pads PD1 and the display area DP-DA of the display panel DP and the shortest distance between the third pads PD3 and the display area DP-DA of the display panel DP. However, the invention is not limited thereto.

In an embodiment, the plurality of pads DP-PD in the chip area DCA may include a first pad column PDL1, a second pad column PDL2, and a third pad column PDL3. Each of the first pad column PDL1, the second pad column PDL2, and the third pad column PDL3 may include a first pad PD1, a second pad PD2, and a third pad PD3 arranged in the second direction DR2. The first pad column PDL1, the second pad column PDL2, and the third pad column PDL3 may be spaced apart from one another in the first direction DR1. A shortest distance between the first pad PD1 and the second pad PD2 may be smaller than a shortest distance between the first pad PD1 and the third pad PD3.

In an embodiment and referring to FIG. 7, the plurality of pads DP-PD may be disposed on at least a portion of the base substrate SUB and the inorganic insulating layer IIL (refer to FIG. 5). More specifically, the plurality of pads DP-PD may be disposed on the second gate insulating layer 113. The plurality of pads DP-PD may be disposed on the same layer and include the same material as the second capacitor plate CE2 of the storage capacitor Cst shown in FIG. 5.

In an embodiment, t plurality of bumpers BP may be arranged at the driving chip DC in 1:1 correspondence with the plurality of pads DP-PD. An anisotropic conductive film ACF may be disposed between the plurality of bumpers BP and the plurality of pads DP-PD, and the anisotropic conductive film ACF may include a conductive ball CB including nickel (Ni). The plurality of bumpers BP of the driving chip DC and the plurality of pads DP-PD of the chip area DCA of the display panel DP may be electrically connected to each other through the conductive ball CB. Thus, through the plurality of pads DP-PD, electrical signals may be applied from the driving chip DC to the sub-pixel circuit PC of the display panel DP.

In an embodiment, in the first pad column PDL1, only the first pad PD1 may be connected to the connection wire CGL. When a signal is applied to the first pad PD1 of the first pad column PDL1, the signal may be applied to the sub-pixel circuit PC through the connection wire CGL connected to the first pad PD1. In the second pad column PDL2, only the second pad PD2 may be connected to the connection wire CGL, and in the third pad column PDL3, only the third pad PD3 may be connected to the connection wire CGL. In other words, a signal may be applied from the driving chip DC to the sub-pixel circuit PC through only the second pad PD2 of the second pad column PDL2 and the third pad PD3 of the third pad column PDL3.

In an embodiment, in the first pad column PDL1, the second pad PD2 and the third pad PD3 that are not connected to the connection wire CGL may be in a floating state. A signal may not be applied through the driving chip DC to the second pad PD2 and the third pad PD3 of the first pad column PDL1 that are not connected to the connection wire CGL.

In an embodiment, in the second pad column PDL2, the first pad PD1 and the third pad PD3 that are not connected to the connection wire CGL may be in a floating state. A signal may not be applied through the driving chip DC to the first pad PD1 and the third pad PD3 of the second pad column PDL2 that are not connected to the connection wire CGL.

In an embodiment, in the third pad column PDL3, the first pad PD1 and the second pad PD2 that are not connected to the connection wire CGL may be in a floating state. A signal may not be applied through the driving chip DC to the first pad PD1 and the second pad PD2 of the third pad column PDL3 that are not connected to the connection wire CGL.

In an embodiment, the plurality of pads DP-PD in the chip area DCA may include a first pad group PDG1. The first pad group PDG1 may include the first pad column PDL1, the second pad column PDL2, and the third pad column PDL3. The first pad group PDG1 may be arranged in the first direction DR1.

In an embodiment, among the first pads PD1, first pads PD1 connected to the connection wire CGL may be spaced apart from each other with two first pads PD1 disposed therebetween not connected to the connection wire CGL. Among the second pads PD2, second pads PD2 connected to the connection wire CGL may be spaced apart from each other with two second pads PD2 disposed therebetween not connected to the connection wire CGL. Among the third pads PD3, third pads PD3 connected to the connection wire CGL may be spaced apart from each other with two third pads PD3 disposed therebetween not connected to the connection wire CGL.

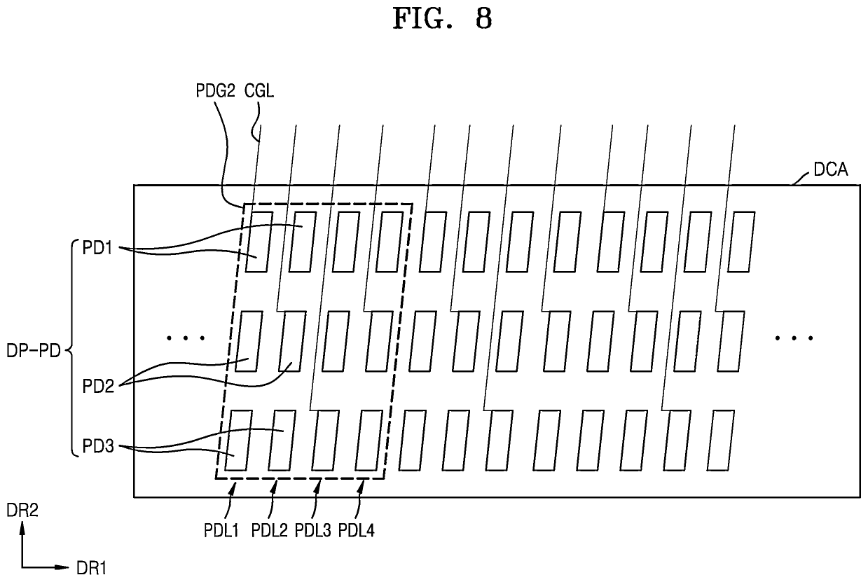

In an embodiment and referring to FIG. 8, the plurality of pads DP-PD may be arranged in the chip area DCA of the display panel DP. The plurality of pads DP-PD in the chip area DCA may include first pads PD1, second pads PD2, and third pads PD3. The first pads PD1 may be arranged in the first direction DR1. The second pads PD2 may be arranged in the first direction DR1 and may be spaced apart from the first pads PD1 in the second direction DR2. The third pads PD3 may be arranged in the first direction DR1 and may be spaced apart from the second pads PD2 in the second direction DR2.

In an embodiment, the plurality of pads DP-PD in the chip area DCA may include a first pad column PDL1, a second pad column PDL2, a third pad column PDL3, and a fourth pad column PDL4. Each of the first pad column PDL1, the second pad column PDL2, the third pad column PDL3, and the fourth pad column PDL4 may include a first pad PD1, a second pad PD2, and a third pad PD3 arranged in the second direction DR2. Each of the first pad column PDL1, the second pad column PDL2, the third pad column PDL3, and the fourth pad column PDL4 may be spaced apart from another in the first direction DR1.

In an embodiment, in the first pad column PDL1, only the first pad PD1 may be connected to the connection wire CGL. When a signal is applied to the first pad PD1 of the first pad column PDL1, the signal may be applied from the driving chip DC to the sub-pixel circuit PC through the connection wire CGL connected to the first pad PD1. In the second pad column PDL2, only the second pad PD2 may be connected to the connection wire CGL, and in the third pad column PDL3, only the third pad PD3 may be connected to the connection wire CGL. In the fourth pad column PDL4, only the second pad PD2 may be connected to the connection wire CGL. In other words, a signal may be applied from the driving chip DC to the sub-pixel circuit PC through only the second pad PD2 of the second pad column PDL2, the third pad PD3 of the third pad column PDL3, and the second pad PD2 of the fourth pad column PDL4.

In an embodiment, in the first pad column PDL1, the second pad PD2 and the third pad PD3 that are not connected to the connection wire CGL may be in a floating state. A signal may not be applied from the driving chip DC to the second pad PD2 and the third pad PD3 of the first pad column PDL1 that are not connected to the connection wire CGL.

In an embodiment, in the second pad column PDL2, the first pad PD1 and the third pad PD3 that are not connected to the connection wire CGL may be in a floating state. A signal may not be applied from the driving chip DC to the first pad PD1 and the third pad PD3 of the second pad column PDL2 that are not connected to the connection wire CGL.

In an embodiment, in the third pad column PDL3, the first pad PD1 and the second pad PD2 that are not connected to the connection wire CGL may be in a floating state. A signal may not be applied from the driving chip DC to the first pad PD1 and the second pad PD2 of the third pad column PDL3 that are not connected to the connection wire CGL.

In an embodiment, in the fourth pad column PDL4, the first pad PD1 and the third pad PD3 that are not connected to the connection wire CGL may be in a floating state. A signal may not be applied through the driving chip DC to the first pad PD1 and the third pad PD3 of the fourth pad column PDL4 that are not connected to the connection wire CGL.

In an embodiment, the plurality of pads DP-PD in the chip area DCA may include a second pad group PDG2. The second pad group PDG2 may include the first pad column PDL1, the second pad column PDL2, the third pad column PDL3, and the fourth pad column PDL4. The second pad group PDG2 may be arranged in the first direction DR1.

In an embodiment, among the first pads PD1, the first pads PD1 that are connected to the connection wire CGL may be spaced apart from each other with three first pads PD1 disposed therebetween not connected to the connection wire CGL. Among the second pads PD2, the second pads PD2 that are connected to the connection wire CGL may be spaced apart from each other with one second pad PD2 disposed therebetween not connected to the connection wire CGL. Among the third pads PD3, the third pads PD3 that are connected to the connection wire CGL may be spaced apart from each other with three third pads PD3 disposed therebetween not connected to the connection wire CGL.

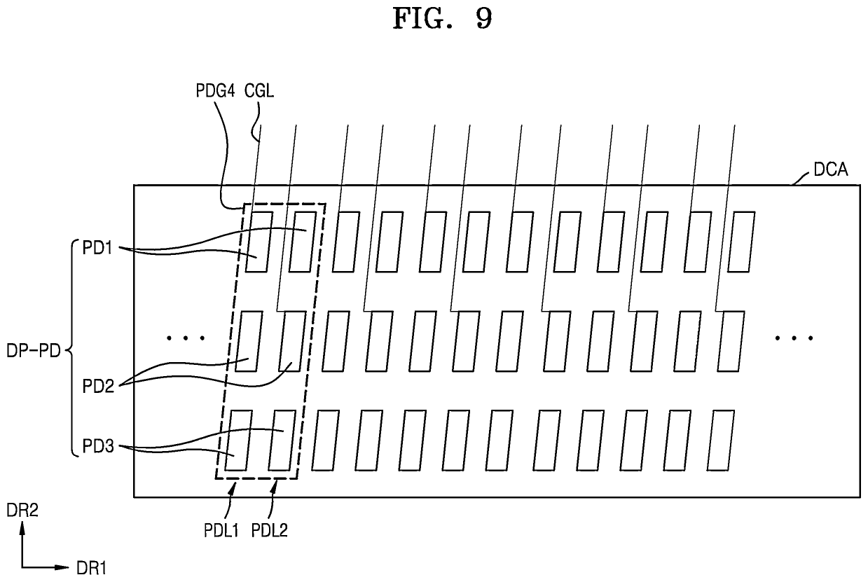

In an embodiment and referring to FIG. 9, the plurality of pads DP-PD may be arranged in the chip area DCA of the display panel DP. The plurality of pads DP-PD in the chip area DCA may include first pads PD1 and second pads PD2. The first pads PD1 may be arranged in the first direction DR1. The second pads PD2 may be arranged in the first direction DR1 and may be spaced apart from the first pads PD1 in the second direction DR2.

In an embodiment, the plurality of pads DP-PD in the chip area DCA may include a first pad column PDL1 and a second pad column PDL2. Each of the first pad column PDL1 and the second pad column PDL2 may include a first pad PD1 and a second pad PD2 arranged in the second direction DR2. The first pad column PDL1 and the second pad column PDL2 may be spaced apart from each other in the first direction DR1.

In an embodiment, in the first pad column PDL1, only the first pad PD1 may be connected to the connection wire CGL. When a signal is applied only to the first pad PD1 of the first pad column PDL1, the signal may be applied from the driving chip DC to the sub-pixel circuit PC through the connection wire CGL connected to the first pad PD1. In the second pad column PDL2, only the second pad PD2 may be connected to the connection wire CGL. When a signal is applied only to the second pad PD2 of the second pad column PDL2, the signal may be applied from the driving chip DC to the sub-pixel circuit PC through the connection wire CGL connected to the second pad PD2.

In an embodiment, in the first pad column PDL1, the second pad PD2 that is not connected to the connection wire CGL may be in a floating state. A signal may not be applied from the driving chip DC to the second pad PD2 of the first pad column PDL1 that is not connected to the connection wire CGL.

In an embodiment, in the second pad column PDL2, the first pad PD1 that is not connected to the connection wire CGL may be in a floating state. A signal may not be applied from the driving chip DC to the first pad PD1 of the second pad column PDL2 that is not connected to the connection wire CGL.

In an embodiment, the plurality of pads DP-PD in the chip area DCA may include a third pad group PDG3. The third pad group PDG3 may include a first pad column PDL1 and a second pad column PDL2. The third pad group PDG3 may be arranged in the first direction DR1.

In an embodiment, among the first pads PD1, first pads PD1 connected to the connection wire CGL may be spaced apart from each other with one first pad PD1 disposed therebetween not connected to the connection wire CGL. Among the second pads PD2, second pads PD2 connected to the connection wire CGL may be spaced apart from each other with one second pad PD2 disposed therebetween not connected to the connection wire CGL.

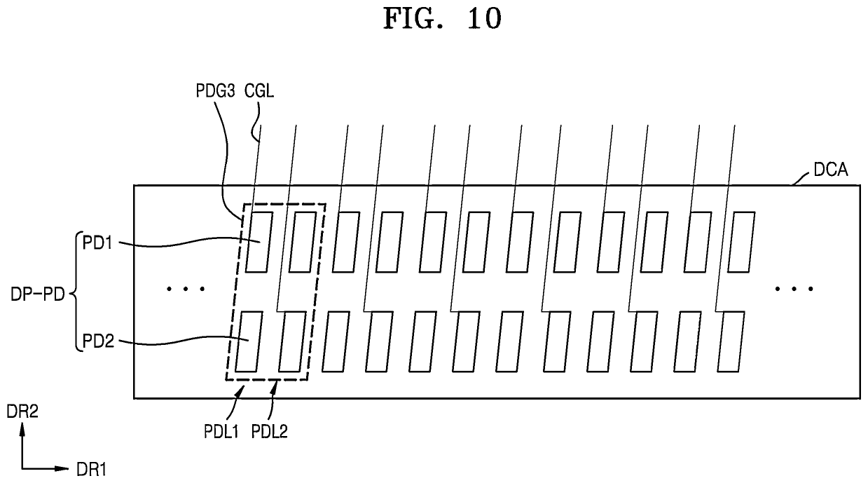

In an embodiment and referring to FIG. 10, the plurality of pads DP-PD may be arranged in the chip area DCA of the display panel DP. The plurality of pads DP-PD may include first pads PD1, second pads PD2, and third pads PD3. The first pads PD1 may be arranged in the first direction DR1. The second pads PD2 may be arranged in the first direction DR1 and may be spaced apart from the first pads PD1 in the second direction DR2. The third pads PD3 may be arranged in the first direction DR1 and may be spaced apart from the second pads PD2 in the second direction DR2.

In an embodiment, the plurality of pads DP-PD in the chip area DCA may include a first pad column PDL1 and a second pad column PDL2. Each of the first pad column PDL1 and the second pad column PDL2 may include a first pad PD1, a second pad PD2, and a third pad PD3 arranged in the second direction DR2. The first pad column PDL1 and the second pad column PDL2 may be spaced apart from each other in the first direction DR1.

In an embodiment, in the first pad column PDL1, only the first pad PD1 may be connected to the connection wire CGL. When a signal is applied only to the first pad PD1 of the first pad column PDL1, the signal may be applied from the driving chip DC to the sub-pixel circuit PC through the connection wire CGL connected to the first pad PD1. In the second pad column PDL2, only the second pad PD2 may be connected to the connection wire CGL. When a signal is applied only to the second pad PD2 of the second pad column PDL2, the signal may be applied from the driving chip DC to the sub-pixel circuit PC through the connection wire CGL connected to the second pad PD2.

In an embodiment, in the first pad column PDL1, the second pad PD2 and the third pad PD3 that are not connected to the connection wire CGL may be in a floating state. A signal may not be applied from the driving chip DC to the second pad PD2 and the third pad PD3 of the first pad column PDL1 that are not connected to the connection wire CGL.

In an embodiment, in the second pad column PDL2, the first pad PD1 and the third pad PD3 that are not connected to the connection wire CGL may be in a floating state. A signal may not be applied from the driving chip DC to the first pad PD1 and the third pad PD3 of the second pad column PDL2 that are not connected to the connection wire CGL.

In an embodiment, the plurality of pads DP-PD in the chip area DCA may include a fourth pad group PDG4. The fourth pad group PDG4 may include a first pad column PDL1 and a second pad column PDL2. The fourth pad group PDG4 may be arranged in the first direction DR1.

In an embodiment, among the first pads PD1, first pads PD1 connected to the connection wire CGL may be spaced apart from each other with one first pad PD1 disposed therebetween not connected to the connection wire CGL. Among the second pads PD2, the second pads PD2 that are connected to the connection wire CGL may be spaced apart from each other with one second pad PD2 disposed therebetween not connected to the connection wire CGL.

When only first pads PD1 from among the plurality of pads DP-PD of the chip area DCA are connected through the connection wire CGL, and signals are applied from the driving chip DC to the sub-pixel circuit PC of the display panel DP through the first pads PD1 and the connection wire CGL, connection wires CGL may be arranged to be disposed adjacent to each other, and thus, nickel (Ni) included in the conductive ball CB may be oxidized in a high-temperature, high-humidity reliability environment, and resistance of the conductive ball CB and the connection wire CGL may increase due to the loss of nickel (Ni), preventing current from flowing.

In an embodiment, to prevent the oxidization of nickel (Ni) included in the conductive ball CB, connection wires CGL are required to be spaced as far apart as possible. According to one or more embodiments, oxidization of nickel (Ni) included in the conductive ball CB may be prevented by spacing connection wires CGL as far apart as possible, and thus, it may be prevented that current does not flow due to an increased resistance of the connection wire CGL.

According to one or more of the above embodiments, a display device with improved reliability and quality may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Accordingly, the scope of the various embodiments of the invention should be interpreted to include, in addition to the embodiments disclosed herein, all alterations or modifications that may be derived from the technical ideas of the various embodiments. Moreover, the embodiments or parts of the embodiments may be combined in whole or in part without departing from the scope of the invention.

What is claimed is:

1. A display device comprising:
a display panel comprising a plurality of pads; and
a driving chip comprising a plurality of bumpers corresponding to the plurality of pads,
wherein the plurality of pads comprise:
a plurality of first pads arranged in a first direction;
a plurality of second pads arranged in the first direction and spaced apart from the plurality of first pads in a second direction crossing the first direction; and
a plurality of third pads arranged in the first direction and spaced apart from the plurality of second pads in the second direction,
wherein a first pad column, a second pad column, and a third pad column each comprise a first pad, a second pad, and a third pad arranged in the second direction,
wherein the second pad column and the third pad column are spaced apart from the first pad column in the first direction,
wherein only the first pad of the first pad column, the second pad of the second pad column, and the third pad of the third pad column are connected to a connection wire,
wherein, in the first pad column, the second pad and the third pad that are not connected to the connection wire are in a floating state.

2. The display device of claim 1, wherein a signal is not applied to the second pad and the third pad of the first pad column that are not connected to the connection wire.

3. The display device of claim 1, wherein, when a signal is applied to the first pad connected to the connection wire, the signal is applied to a sub-pixel circuit through the connection wire.

4. The display device of claim 1, wherein, in the second pad column, the first pad and the third pad that are not connected to the connection wire are in a floating state.

5. The display device of claim 1, wherein, in the third pad column, the first pad and the second pad that are not connected to the connection wire are in a floating state.

6. The display device of claim 1, wherein a first pad group comprises the first pad column, the second pad column, and the third pad column,
wherein the first pad group is arranged in the first direction.

7. The display device of claim 6, wherein the first pads that are connected to the connection wire are spaced apart from each other with two of the first pads disposed therebetween that are not connected to the connection wire.

8. The display device of claim 6, wherein the second pads that are connected to the connection wire are spaced apart from each other with two of the second pads disposed therebetween that are not connected to the connection wire.

9. The display device of claim 6, wherein the third pads that are connected to the connection wire are spaced apart from each other with two of the third pads disposed therebetween that are not connected to the connection wire.

10. A display device comprising:
a display panel comprising a plurality of pads; and
a driving chip comprising a plurality of bumpers corresponding to the plurality of pads,
wherein the plurality of pads comprise:
a plurality of first pads arranged in a first direction;
a plurality of second pads arranged in the first direction and spaced apart from the plurality of first pads in a second direction crossing the first direction; and
a plurality of third pads arranged in the first direction and spaced apart from the plurality of second pads in the second direction,
wherein a first pad column, a second pad column, a third pad column, and a fourth pad column each comprise a first pad, a second pad, and a third pad arranged in the second direction,
wherein the first pad column, the second pad column, the third pad column, and the fourth pad column are spaced apart from one another in the first direction,
wherein only the first pad of the first pad column, the second pad of the second pad column, the third pad of the third pad column, and the second pad of the fourth pad column are connected to a connection wire,
wherein, in the first pad column, the second pad and the third pad that are not connected to the connection wire are in a floating state.

11. The display device of claim 10, wherein, in the second pad column, the first pad and the third pad that are not connected to the connection wire are in a floating state.

12. The display device of claim 10, wherein, in the third pad column, the first pad and the second pad that are not connected to the connection wire are in a floating state.

13. The display device of claim 10, wherein, in the fourth pad column, the first pad and the third pad that are not connected to the connection wire are in a floating state.

14. The display device of claim 10, wherein a second pad group comprises the first pad column, the second pad column, the third pad column, and the fourth pad column,
wherein the second pad group is arranged in the first direction.

15. The display device of claim 10, wherein the first pads that are connected to the connection wire are spaced apart from each other with three of the first pads disposed therebetween that are not connected to the connection wire.

16. The display device of claim 10, wherein the second pads that are connected to the connection wire are spaced apart from each other with the second pad disposed therebetween that is not connected to the connection wire.

17. The display device of claim 10, wherein the third pads that are connected to the connection wire are spaced apart from each other with three of the third pads disposed therebetween that are not connected to the connection wire.

18. A display device comprising:
a display panel comprising a plurality of pads; and
a driving chip comprising a plurality of bumpers corresponding to the plurality of pads,
wherein the plurality of pads comprise:
a plurality of first pads arranged in a first direction; and
a plurality of second pads arranged in the first direction and spaced apart from the plurality of first pads in a second direction crossing the first direction,
wherein a first pad column and a second pad column each comprise a first pad and a second pad arranged in the second direction,
wherein the first pad column and the second pad column are spaced apart from each other in the first direction,
wherein the first pad of the first pad column and the second pad of the second pad column are connected to a connection wire,
wherein, in the first pad column, the second pad that is not connected to the connection wire is in a floating state.

19. The display device of claim 18, wherein, in the second pad column, the first pad that is not connected to the connection wire is in a floating state.

20. The display device of claim 18, wherein a third pad group comprises the first pad column and the second pad column,
wherein the third pad group is arranged in the first direction.
